(19) United States
(12) Patent Application Publication
(10) Pub. No.: US 2022/0076978 A1
(43) Pub. Date: Mar. 10, 2022

(54) ALIGNMENT OF AN ELECTROSTATIC CHUCK WITH A SUBSTRATE SUPPORT

(71) Applicant: Applied Materials, Inc., Santa Clara, CA (US)

(72) Inventors: Bhaskar PRASAD, Jamshedpur (IN); Kirankumar Neelasandra SAVANDAIAH, Bangalore (IN); Thomas BREZOCZKY, Los Gatos, CA (US); Nitin Bharadwaj SATYAVOLU, Kakinada (IN); Srinivasa Rao YEDLA, Bangalore (IN)

(21) Appl. No.: 17/016,010

(22) Filed: Sep. 9, 2020

(51) Int. Cl. H01L 21/68; H01L 21/683; H01L 21/687; B65G 47/92

(52) U.S. Cl. CPC H01L 21/68; B65G 47/92; H01L 21/68742; H01L 21/6833

(57) ABSTRACT

In one example, a substrate support for a processing chamber comprises a plurality of pins and a plurality of alignment elements. The plurality of pins are configured to mate with terminals of an electrostatic chuck. The plurality of pins are configured to be coupled to one or more power sources. The plurality of alignment elements are configured to interface with a plurality of centering elements of the electrostatic chuck to center the electrostatic chuck with the substrate support. Each of the plurality of alignment elements is configured to interface with a slot of a corresponding one of the plurality of centering elements.

### BACKGROUND

### Field

Embodiments of the present disclosure generally relate to a methods and apparatus for processing substrates. More particularly, embodiments of the disclosure relate to substrate processing platforms, which use multiple processing chambers for processing substrates.

### Description of the Related Art

Conventional semiconductor wafer processing equipment, typically referred to as cluster tools, are configured to perform one or more processes during substrate processing. For example, a cluster tool can include a physical vapor deposition (PVD) chamber to perform a PVD process on a substrate, an atomic layer deposition (ALD) chamber for performing an ALD process on a substrate, a chemical vapor deposition (CVD) chamber for performing CVD processes on a substrate, and/or one or more other processing chambers.

In semiconductor wafer processing equipment, substrate supports are used for retaining substrates (or wafers) during processing. The substrate rests on a susceptor, for example an electrostatic chuck. Electrostatic chucks (or chuck) secure a substrate by creating an electrostatic attractive force between the substrate and the electrostatic chuck. A voltage applied to one or more insulated electrodes in the electrostatic chuck induces opposite polarity charges in the surface of the substrate and substrate supporting surface of the electrostatic chuck, respectively. The opposite charges generate a “chucking force” which causes the substrate to be pulled onto or attracted to the substrate supporting surface of the electrostatic chuck, thereby retaining the substrate. Conventional electrostatic chuck designs include assemblies that are inseparable due to the need to form good thermal and electrical coupling with various internal (e.g., cooling channels, electrical wires/leads connections) and external components (e.g., power supplies), and allow portions of the electrostatic chuck assembly to be disposed within a vacuum environment.

Many thin film deposition and etch processes performed in conventional semiconductor wafer processing equipment employ single substrate processing chambers that are attached to a mainframe of the cluster tool, wherein a single substrate is loaded into a dedicated vacuum process chamber having dedicated hardware therein to support the substrate during a process performed thereon. The time required to load and unload the substrate from the dedicated chamber using a robot that is able to pick up and transfer one wafer at a time, which commonly includes the time needed to chuck and de-chuck the substrate from the substrate support in each process chamber, adds overhead time to the total time required to process a substrate in a cluster tool, decreases throughput and increases cost of ownership (CoO).

Thus, the aforementioned cluster tools and substrate supporting hardware have limitations, such as mechanical throughput, substrate thermal stability during processing, and process flexibility. Therefore, what is needed in the art is a transfer apparatus for the cluster tool capable of improving the mechanical throughput, substrate thermal stability, and increasing process flexibility. Thus, there is also a need for a substrate support assembly and substrate transfer mechanism, and method of using the same, that solves the problems described above.

### SUMMARY

In one example, a substrate support for a processing chamber comprises a plurality of pins and a plurality of alignment elements. The plurality of pins are configured to mate with terminals of an electrostatic chuck. The plurality of pins are configured to be coupled to one or more power sources. The plurality of alignment elements are configured to interface with a plurality of centering elements of the electrostatic chuck to center the electrostatic chuck with the substrate support. Each of the plurality of alignment elements is configured to interface with a slot of a corresponding one of the plurality of centering elements.

In one example, a processing region comprises one or more power sources and a pedestal assembly. The one or more power sources are configured to provide power signals. The pedestal assembly comprises a substrate support. The substrate support comprises a plurality of pins configured to mate with a plurality of terminals of an electrostatic chuck. The plurality of pins are coupled to the one or more power sources. The plurality of alignment elements are configured to interface with a plurality of centering elements of the electrostatic chuck to center the electrostatic chuck with the substrate support. Each of the plurality of alignment elements is configured to interface with a slot of a corresponding one of the plurality of centering elements.

In one example, a method for transferring an electrostatic chuck and a substrate onto a substrate support of a processing region comprises aligning the electrostatic chuck and the substrate with the substrate support by interfacing a plurality of alignment elements of the substrate support with a plurality of centering elements of the electrostatic chuck. The method further comprises forming an electrical contact between one more pins of the substrate support and one or more terminals of the electrostatic chuck. Further, the method comprises interfacing a flexible element of the substrate support with a passageway of the electrostatic chuck.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a plan view of a cluster tool assembly, according to one embodiments.

FIG. 2 illustrates a central transfer apparatus, according to one or more embodiments.

FIG. 3 illustrates a support arm, an electrostatic chuck, and a substrate, according to one or more embodiments.

FIG. 4 illustrates a portion of a central transfer apparatus, according to one or more embodiments.

FIGS. 5 and 6 illustrate a side view of a processing region, according to one or more embodiments.

FIGS. 7 illustrates a substrate support, an electrostatic chuck, and a substrate, according to one or more embodiments.

FIG. 8 illustrates a top view of a substrate support, according to one or more embodiments.

FIG. 9 illustrates an alignment element and a centering element, according to one or more embodiments.

FIG. 10 illustrates a centering element, according to one or more embodiments.

FIGS. 11, 12, 13, 14 and 15 illustrate a substrate support, an electrostatic chuck, and a substrate at various different positions, according to one or more embodiments.

FIG. 16 illustrates a method for transferring an electrostatic chuck and a substrate into a processing region, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Before describing several exemplary embodiments of the apparatus and methods, it is to be understood that the disclosure is not limited to the details of construction or process steps set forth in the following description. It is envisioned that some embodiments of the present disclosure may be combined with other embodiments.

One or more embodiments of the present disclosure are directed towards an apparatus for substrate processing and a cluster tool including a central transfer apparatus and a plurality of processing stations that each include a processing region. The central transfer apparatus, which is also referred to herein as the transfer apparatus, is configured as a carousel in some embodiments, and the processing regions may include facilities to enable atomic layer deposition (ALD), chemical vapor deposition (CVD), physical vapor deposition (PVD), etch, cleaning, heating, annealing, and/or polishing processes. Other processing platforms may also be used with the present disclosure at the discretion of a user. The present disclosure is generally meant to provide a substrate processing tool with high throughput, increased adaptability, and a smaller footprint.

Aspects of the disclosure provided herein generally provide a substrate processing system that includes at least one processing module that includes a plurality of processing stations coupled thereto and a substrate transferring device disposed within a transfer region of the processing module for transferring a plurality of substrates to two or more of the plurality of processing stations. The methods and apparatuses disclosed herein are useful for performing vacuum processing on substrates wherein one or more substrates are transferred within the transfer region of the processing module that is in direct communication with at least a portion of a processing region of a plurality of separately isolatable processing stations during the process of transferring the one or more substrates. In some embodiments, a substrate is positioned and maintained on the same substrate support member (hereafter electrostatic chuck) during the process of transferring the substrate within the processing module and while the substrate is being processed in each of the plurality of processing stations.

In the substrate processing system, or cluster tool assembly, both an electrostatic chuck and a substrate are transferred between processing chamber of the cluster tool assembly. As is discussed further below, when the electrostatic chuck and substrate are transferred between processing chambers, the terminals of the electrostatic chuck need to mate with pins of different substrate supports, which are positioned at each of the different processing stations, to allow an electrical connection to be reliably formed between each of the different substrate supports. The pins of the substrate support provide power signals to the terminals of the electrostatic chuck. As is discussed further below, in some embodiments, the pins of the substrate support are configured to support a portion of the weight of the electrostatic chuck to ensure that the electrical connection between the pins of the substrate support and the terminals of the electrostatic chuck allows power signals to be repeatedly and reliably transferred.

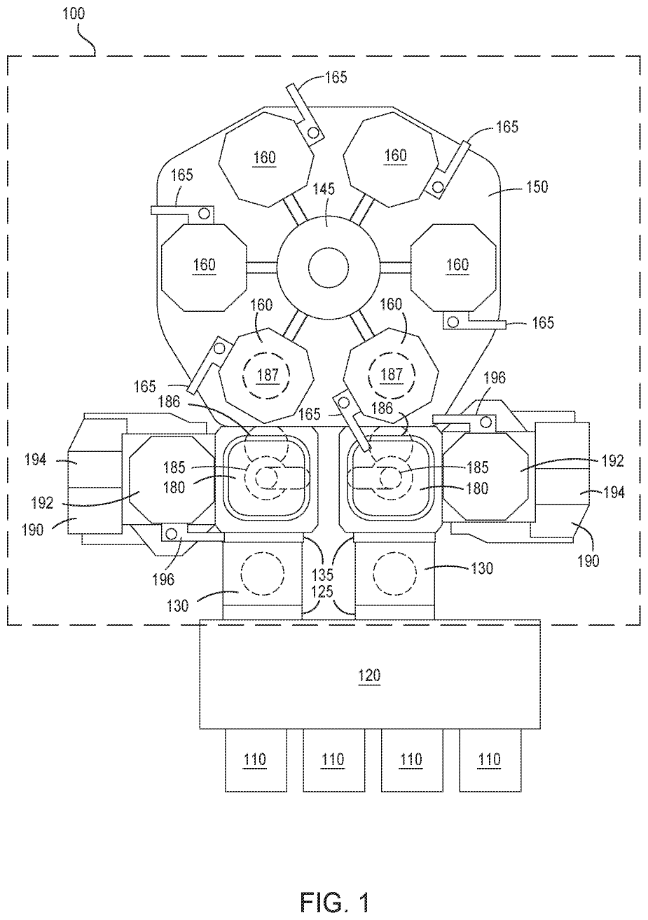

FIG. 1 is a plan view of a cluster tool assembly 100 with a single transfer chamber assembly 150. The cluster tool assembly 100 includes a plurality of load lock chambers 130, a plurality of robot chambers 180 adjacent to the plurality of load lock chambers 130, a plurality of prep chambers 190 adjacent to the plurality of robot chambers 180, and the transfer chamber assembly 150 adjacent to the plurality of robot chambers 180. The load lock chambers 130 of the cluster tool assembly 100 are typically coupled to a plurality of Front Opening Unified Pods (FOUPs) 110 by a Factory Interface (FI) 120 adjacent to the FOUPs 110.

The plurality of FOUPs 110 may be utilized to safely secure and store substrates as the substrates are moved between different machines. The plurality of FOUPs 110 may vary in quantity depending upon the process and throughput of the system. The FI 120 is disposed between the plurality of FOUPs 110 and the plurality of load lock chambers 130. The FI 120 creates an interface between the factory and the cluster tool assembly 100. The plurality of load lock chambers 130 are connected to the FI 120 by first valves 125, such that a substrate may be transferred from the FI 120 to the plurality of load lock chambers 130 through the first valves 125 and from the plurality of load lock chambers 130 to the FI 120. As shown, the first valves 125 are on one wall of the load lock chambers 130. In some embodiments, the first valves 125 are fluid isolation valves and form a seal between the FI 120 and the load lock chambers 130. This seal may keep outside contaminants from entering the cluster tool assembly 100. The load lock chambers 130 also comprise a second valve 135 on an opposite wall from the first valve 125. The second valve 135 interfaces the load lock chambers 130 with the robot chambers 180.

The transfer chamber assembly 150 includes a central transfer apparatus 145 and a plurality of processing stations 160. The plurality of processing stations 160 are disposed around the central transfer apparatus 145, such that the plurality of processing stations 160 are disposed radially outward of the central transfer apparatus 145 in the transfer chamber assembly 150.

As shown, the robot chambers 180 are on one side of the load lock chambers 130, such that the load lock chambers 130 are between the FI 120 and the robot chambers 180. The robot chambers 180 include a transfer robot 185. The transfer robot 185 may be any robot suitable to transfer one or more substrates from one chamber to another. The transfer robot 185 is utilized to transfer substrates 186 to an electrostatic chuck (e.g., electrostatic chuck) 187 that is temporarily connected to the central transfer apparatus 145. The separable connection between the electrostatic chuck 187 and the central transfer apparatus 145 is described below in more detail. The electrostatic chuck 187 holds a single substrate 186 and travels with the substrate 186 to each of the processing stations 160. The electrostatic chuck 187, when in one of the processing stations 160 (with a substrate thereon), forms a boundary of the processing station 160. The substrates 186 are mated with one electrostatic chuck 187, and the substrate 186 moves in and between the processing stations 160 on that electrostatic chuck 187.

In some embodiments, the transfer robot 185 is configured to transport substrates 186 from the load lock chambers 130 and into the plurality of prep chambers 190. The transfer robot 185 removes the substrate 186 from the load lock chambers 130, moves the substrate 186 into the robot chamber 180, and then moves the substrate 186 into the prep chamber 190. The transfer robot 185 is also be configured to move substrates 186 to the transfer chamber assembly 150. Similarly to how the substrate 186 may be moved to the prep chambers 190 from the load lock chambers 130 by the transfer robot 185, the substrate 186 may also be moved from the prep chamber 190 to the load lock chambers 130 by the transfer robot 185. The transfer robot 185 may also move substrates 186 from the transfer chamber assembly 150 to the prep chambers 190 or the load lock chambers 130. In some alternative embodiments, the transfer robot 185 may move a substrate 186 from the load lock chambers 130, move the substrate 186 into the robot chamber 180, and then move the substrate 186 into the transfer chamber assembly 150. In this alternative embodiment, the substrate 186 may not enter the prep chamber 190 either before processing in the transfer chamber assembly 150 or after processing in the transfer chamber assembly 150.

The prep chambers 190 include a cleaning chamber 192, a packaging structure 194, and a cleaning chamber vacuum pump 196. The cleaning chamber 192 may be any one of a pre-clean chamber, an anneal chamber, or a cool down chamber, depending upon the desired process within the cluster tool assembly 100. In some embodiments, the cleaning chamber 192 is a wet clean chamber. In other embodiments, the cleaning chamber 192 is a plasma clean chamber. In yet other exemplary embodiments, the cleaning chamber 192 is a Preclean II chamber available from Applied Materials, Inc., of Santa Clara, Calif.

The packaging structure 194 may be a structural support for the cleaning chamber 192. The packaging structure 194 may include a sub-transfer chamber (not shown), a gas supply (not shown), and an exhaust port (not shown). The packaging structure 194 may provide the structure around the cleaning chamber 192 and interface the cleaning chamber 192 to the robot chamber 180. The cleaning chamber vacuum pump 196 is disposed adjacent to a wall of the cleaning chamber 192 and provides control of the pressure within the cleaning chamber 192. One cleaning chamber vacuum pump 196 may be adjacent to each of the cleaning chambers 192. The cleaning chamber vacuum pump 196 may be configured to provide a pressure change to the cleaning chamber 192. In some embodiments, the cleaning chamber vacuum pump 196 is configured to increase the pressure of the cleaning chamber 192. In other embodiments, the cleaning chamber vacuum pump 196 is configured to decrease the pressure of the cleaning chamber 192, such as to create a vacuum within the cleaning chamber 192. In yet other embodiments, the cleaning chamber vacuum pump 196 is configured to both increase and decrease the pressure of the cleaning chamber 192 depending on the process being utilized within the cluster tool assembly 100. The cleaning chamber vacuum pump 196 may be held in place by the packaging structure 194, such that the packaging structure 194 at least partially surrounds the cleaning chamber vacuum pump 196.

The load lock chambers 130, robot chambers 180, and prep chambers 190 may be arranged to reduce the footprint required for the cluster tool assembly 100. In one embodiment, one load lock chamber 130 is attached to a first wall of the robot chamber 180. One prep chamber 190 is attached to a second wall of the robot chamber 180. The first and second walls may be adjacent walls on the robot chamber 180. In some embodiments, the robot chamber 180 is roughly square shaped. In other embodiments, the robot chamber 180 is a quadrilateral. In yet other embodiments, the robot chambers 180 may be any desired shape, such as a polygon or a round shape, such as a circle. In an embodiment where the robot chambers 180 are a square or quadrilateral shape, the first wall and the second wall may be adjacent walls, such that the two walls intersect each other. As shown in FIG. 1, the cluster tool assembly 100 includes two load lock chambers 130, two robot chambers 180, and two cleaning chambers 190. The two load lock chambers 130, two robot chambers 180, and two cleaning chambers 190, when arranged as described above, form two transport assemblies. The two transport assemblies are spaced apart from each other and form mirror images of one another, such that the prep chambers 190 are on opposite walls of their respective robot chambers 180.

As shown, the transfer chamber assembly 150 is adjacent to the robot chambers 180, such that the transfer chamber assembly 150 is connected to the robot chambers 180 by a slit valve (not shown). The transfer chamber assembly 150 may be attached to a third wall of the robot chambers 180. The third wall of the robot chambers 180 may be opposite the first wall of the robot chambers 180.

A chamber pump 165 is disposed adjacent to each of the processing stations 160, such that a plurality of chamber pumps 165 are disposed around the central transfer apparatus 145. The plurality of chamber pumps 165 may also be disposed radially outward of the central transfer apparatus 145 in the transfer chamber assembly 150. One chamber pump 165 for each of the processing stations 160 is provided, such that one chamber pump 165 is connected to each of the processing stations 160. In some embodiments, multiple chamber pumps 165 per processing station 160 are provided. In yet other embodiments, a processing station 160 may not have a chamber pump 165. A varying number of chamber pumps 165 per processing station 160 may be provided, such that one or more processing stations 160 may have a different number of chamber pumps 165 than a separate set of processing stations 160. In some embodiments, the chamber pumps 165 are configured to increase the pressure of the processing station 160. In other embodiments, the chamber pumps 196 are configured to decrease the pressure of the processing region 560 of the processing station 160, such as to create a vacuum within the processing region 560. In yet other embodiments, the chamber pumps 165 are configured to both increase and decrease the pressure within the processing region 560 of the processing stations 160 depending on the process being utilized within the cluster tool assembly 100.

In the embodiment shown in FIG. 1, the transfer chamber assembly 150 includes six processing stations 160. In one embodiment, the transfer chamber assembly 150 includes a single processing station 160. In another embodiment, two or more processing stations 160 are provided. In some embodiments two to twelve processing stations 160 are within the transfer chamber assembly 150. In other embodiments, four to eight processing stations 160 are within the transfer chamber assembly 150. The number of processing stations 160 impacts the total footprint of the cluster tool assembly 100, the number of possible process steps capable of being performed by the cluster tool assembly 100, the total fabrication cost of the cluster tool assembly 100, and the throughput of the cluster tool assembly 100.

The plurality of processing stations 160 can be any one of PVD, CVD, ALD, etch, cleaning, heating, annealing, and/or polishing platforms. In some embodiments, the plurality of processing stations 160 can all be similar platforms. In other embodiments, the plurality of processing stations 160 can include two or more types of processing platforms. In one exemplary embodiment, all of the plurality of processing stations 160 are PVD process chambers. In another exemplary embodiment, the plurality of processing stations 160 includes both PVD and CVD process chambers. Other embodiments of the makeup of the plurality of processing stations 160 are envisioned. The plurality of processing stations 160 can be altered to match the types of process chambers needed to complete a process.

The central transfer apparatus 145 is disposed in the center of the transfer chamber assembly 150, such that the central transfer apparatus 145 is disposed around a central axis of the transfer chamber assembly 150. The central transfer apparatus 145, may be any suitable transfer device. The central transfer apparatus 145 is configured to transport a substrate 186 on an electrostatic chuck 187 to and from each of the processing stations 160. In one embodiment, the central transfer apparatus 145 is configured as a carousel system.

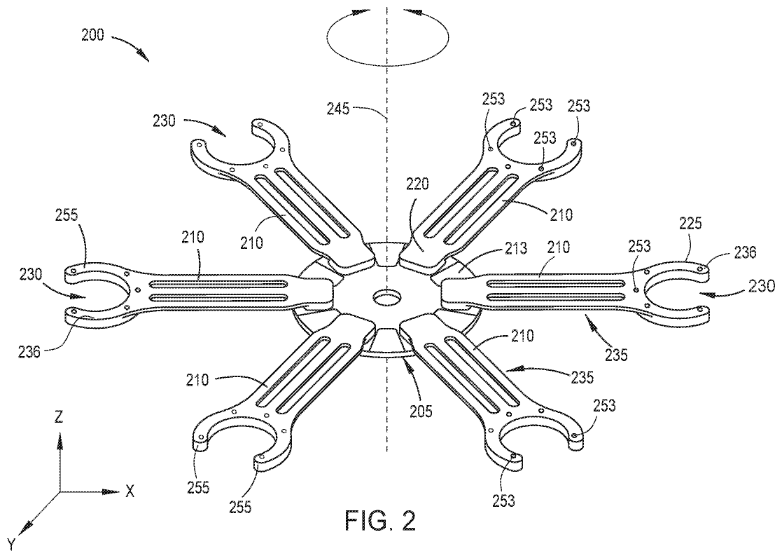

FIG. 2 is a perspective view of one embodiment of a central transfer apparatus 145 that includes a carousel 200. The carousel 200 may be included within the central transfer apparatus 145 of FIG. 1 according to embodiments of the disclosure described herein. The carousel 200 includes a hub 205 and a plurality of transfer arms 210. Each of the transfer arms 210 may be positionable relative to the hub 205 (e.g., in the X direction, the Y direction, and the Z direction, and combinations thereof). Each of the transfer arms 210 may also be angularly adjusted relative to the hub 205. The transfer arms 210 may be detachable from the hub 205. In some embodiments, the transfer arms 210 are mechanically coupled to the hub 205, such as by one or more fastening members, such as bolts or screws.

The hub 205 may include a plurality of arm fixing areas 213. The plurality of arm fixing areas 213 may be configured to allow a first (inner or a proximal) end 220 of each of the transfer arms 210 to be coupled to the hub 205. The first end 220 of each of the transfer arms 210 is positioned radially inward of a second (outer or distal) end 225 of the transfer arms 210. The first end 220 includes a mounting region of the transfer arm 210 that is coupled to the hub 205. The second end 225 of each of the transfer arms 210 include a component supporting region. The component supporting region of the second end 225 may have an opening 230 facing away from the hub 205. The opening 230 is sized to allow a portion of a robot blade or arm (not shown) to extend at least partially therein. An arm body or connecting member 235, which is part of the respective transfer arm 210, is disposed between and connects the second end 225 to the first end 220.

In some embodiments, the carousel 200 is a mechanical assembly that includes at least one degree of freedom. In one configuration, the carousel 200 is capable of rotating about a rotational axis 245 by use of a rotational motor. In another configuration, the carousel 200 is capable of rotating about a rotational axis 245 by use of a rotational motor, and moving in a direction parallel to the rotational axis 245 by use of a vertical actuator/motor.

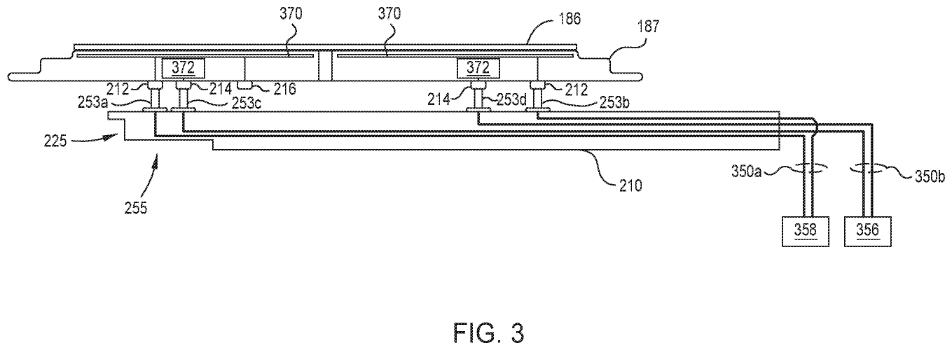

At least a portion of the transfer arms 210 include a plurality of electrical contacts 253 positioned on the component supporting region of the second end 225. The electrical contacts 253 are utilized to provide electrical power to or through the transfer arms 210 to a component (e.g., the electrostatic chuck 187) that is supported on the component supporting region of the transfer arm 210. The electrical contacts 253 may be electrical contact pins extending from a surface of the component supporting region of the second end 225 of the transfer arms 210. Each of the electrical contacts 253 are adapted for contact mating electrical contacts/connections on a backside of the electrostatic chuck 187 and are configured to provide electrical power to electrical components (e.g., heating elements 372 and/or chucking electrodes 370 of FIG. 3) disposed within the electrostatic chuck 187 when the electrostatic chuck 187 is positioned thereon. The electrical contacts 253 may be fixed or compliant in at least one direction (e.g., Z-direction in FIG. 2).

The number of transfer arms 210 may be an even number or odd number. For example, the carousel 200 may have two or more transfer arms 210.

An example of a six transfer arm 210 configuration is illustrated in FIG. 2. The number of transfer arms 210 may equal the number of processing stations 160 (shown in FIG. 1).

FIG. 3 is a schematic sectional side view of a portion of one of the transfer arms 210 of the carousel 200 of FIG. 2. The electrical contacts 253 (e.g., contacts 253a-253d in FIG. 3) are at the second end 225 of the transfer arm 210. Also shown is the electrostatic chuck 187 supported by the component supporting region at the fork 255. A substrate 186 is shown attached to the electrostatic chuck 187, which is supported by the transfer arm 210.

Each of the electrical contacts 253 may be shaped as a protruding member or pin. The electrical contacts 253a and 253b contact and form an electrical connection with the terminals 212 of the electrostatic chuck 187. Additionally, or alternatively, the electrical contacts 253c and 253d contact and form an electrical connection with one or more of the terminals 214. In one or more embodiments, the electrical contacts 253c and 253d are omitted such that the transfer arm 210 includes the electrical interface connects 253a and 253b, and not the electrical contacts 253c and 253d.

The electrical contacts 253 provide electrical power to an electrical component or components within the electrostatic chuck 187 while the electrostatic chuck 187 and substrate 186 are supported on the transfer arm 210. For example, the electrical contacts 253a and 253b is coupled to a power source 358 that provides direct current (DC) signals, e.g., a DC power source, via connections 350a. The DC signals are coupled the chucking electrodes 370 via the electrical connection between the electrical contacts 253a, 253b and the terminals 212. A first one of the DC signals has a positive polarity and a second one of the DC signals has a negative polarity. Further, the magnitude of the DC signals are substantially similar (e.g., within five percent of each other). For example, the magnitude of the DC signals is about 1000 V. Alternatively, the magnitude of the DC signals is less than or greater than about 1000 V. Driving the chucking electrodes 370 with the DC signals generates an electrical chucking force that holds the substrates 186 to the surface of the electrostatic chuck 187.

The power source 356 provides an alternating current (AC) signal or signals that is provided to the heating elements 372 via the electrical connection between an electrical contact 253 and a terminal 214. The power source 356 is connected to the electrical contacts 253c and 253d via connections 350d. The power source 356 may be referred to as an AC power source. The AC signal provide a current of about 30 A. Alternatively, the AC signal provides a current of less than or greater than 30 A. The AC signal or signals are converted by the heating elements 372 into heat that thermally couples with the substrate 186.

The conductors 350 are routed through an internal region of the transfer arm 210 to connect with the respective ones of the electrical contacts 253.

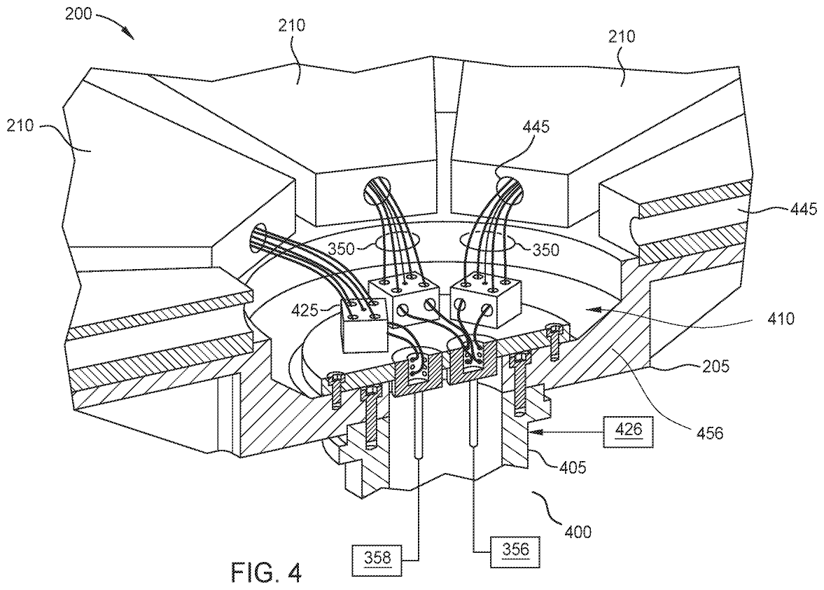

As illustrated in FIG. 4, the electrical contacts 253 are electrically coupled to the power supplies 356 and 358 by use of a slip ring 456 that is adapted to allow electrical connections to be made to the electrical contacts 253 while the transfer arms 210 are rotated by a carousel motor 426. FIG. 4 illustrates a schematic sectional perspective view of an example shaft assembly 400 of the carousel 200, according to one or more embodiments. The shaft assembly 400 includes a hollow shaft 405 that is coupled to the hub 205. Each of the plurality of transfer arms 210 is coupled to the hub 205. The hub 205 includes a recessed portion 410 formed in a center thereof. A central cap of the hub 205 is disposed in the recessed portion 410. The central cap is utilized to fix the hub 205 to the hollow shaft 405, for example, using fasteners.

The central cap includes a plurality of terminal blocks 425 mounted thereon. Each of the terminal blocks 425 may include a metal containing ceramic material or a polymer, such as polyether ether ketone (PEEK). Each of the terminal blocks 425 are configured to distribute electrical power provided from a plurality of sealed feed-throughs 445 formed between the hollow shaft 405 and the central cap 415. The sealed feed-throughs 445 may be a vacuum-tight electrical feed-through that is configured to transfer power from an interior volume 435 of the hollow shaft 405, which is at ambient or atmospheric pressures while the transfer arms 210 and upper portion of the hub 205 and other portions connected thereto are positioned within a transfer region that is at a negative pressure during use.

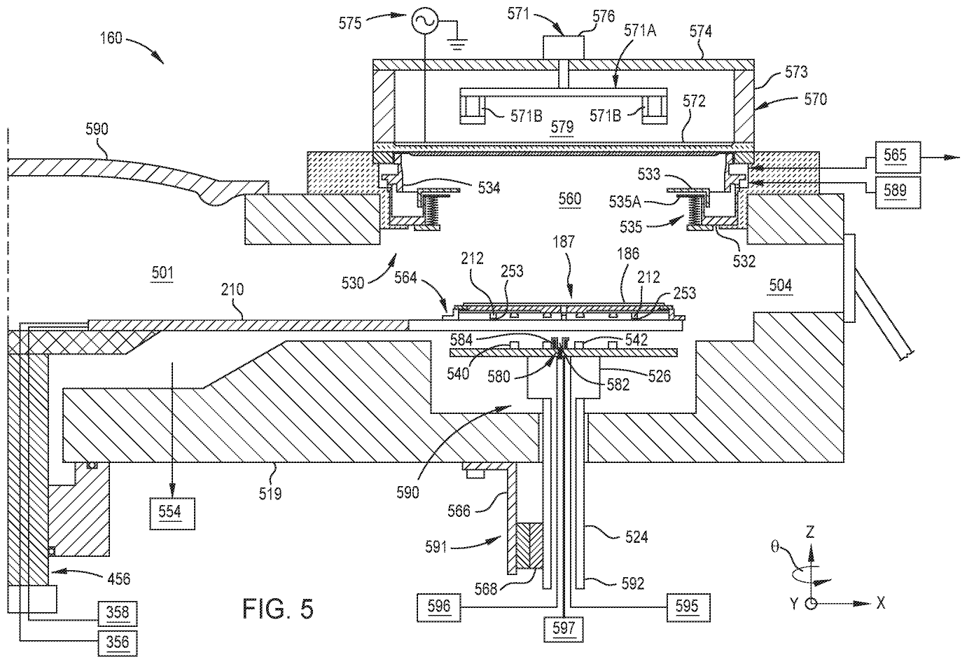

The feed-throughs 445 are separately coupled to the heater power source 356 (AC) and the chucking power source 358 (DC). Typically, one of each power source is operably coupled to each transfer arm 210. Wires are provided to the terminal blocks 425 from the feed-through 445 to the terminal blocks 425, and conductors 350 are provided from the terminal blocks 425 on or through each of the plurality of transfer arms 210 to supply power to the electrical interface connections (e.g., electrical contacts 253 of FIG. 2). In one embodiment, conductors 350 from the terminal blocks 425 are routed via through-holes 445 formed in each of the plurality of transfer arms 210. With reference to FIG. 2, when the electrostatic chuck 187 is positioned on the supporting portion of the transfer arm 210, the terminals 214, 216 of the electrostatic chuck 187 are electrically coupled to the electrical contacts 253 of the transfer arms 210 so that a substrate can remain chucked to the electrostatic chuck 187 and a desired temperature can be maintained while the substrate 186 and electrostatic chuck 187 are being transferred within the transfer region (e.g. the transfer region 501 of FIG. 5) between processing stations 160. The ability to allow the substrate 186 to be chucked and heated during a transferring process allows greater rotational speeds to be achieved by the carousel motor 426 during a transfer process without the concern of losing the substrate, and allows the temperature of the substrate to be consistently maintained between processes performed in each processing station 160.

In some embodiments, at least one separate power source is configured to separately control the power delivered to each portion of the electrical circuits formed in each of the transfer arms 210 in the carousel, which is illustrated in FIGS. 3. In one example, a six transfer arm 210 carousel design includes six AC power supplies 356 and six DC power supplies 358 that are each separately dedicated to a portion of an electrical circuit formed in one of the transfer arms 210. However, the number of terminal blocks that would be required to allow each portion of the electrical circuits to be controlled independently can be less than a more conventional direct wiring type of design, since some of the terminal blocks can be used as a common reference point (FIG. 4) in each of the electrical circuits in each of the transfer arms 210. For example, in one configuration, only 20 terminal blocks are required for a five wire per transfer arm (i.e., 3 wires for the AC power and 2 wires for the DC power and five electrical contacts 253 per transfer arm 210) and six transfer arms 210 on a carousel 200 configuration, since one of the terminals in each of the AC power supplies 356 are connected to a single terminal block 425 (e.g., right-side terminal block in FIG. 4) and one of the terminals in each of the DC power supplies 358 are connected to a single terminal block 425 (e.g., left-side terminal block in FIG. 4), thus effectively removing the need for 10 terminal blocks in this configuration.

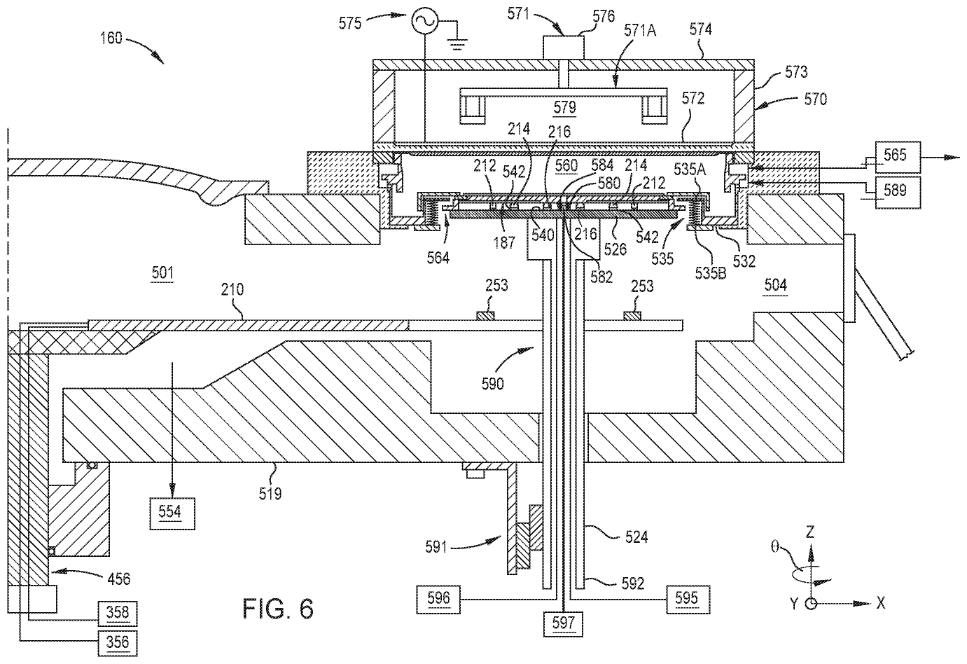

As shown in FIGS. 5 and 6, a processing station 160 is serviced via the central transfer apparatus (the central transfer apparatus 145 of FIG. 1) to transfer electrostatic chucks (e.g., the electrostatic chuck 187) and substrates (e.g., the substrate 186) into and out of the processing station 160. The processing station 160 includes a substrate transfer opening 504 that extends inwardly of the outer surface of a circumferential wall of a transfer chamber assembly 150 (e.g., the transfer chamber assembly 150 of FIG. 1) and into the transfer region 501 of the transfer chamber assembly. The transfer opening 504 allows a transfer robot (e.g., the transfer robot 185), to transfer the substrate 186 into and out of the transfer region 501.

The source assembly 570 of the processing station 160 is configured to perform a deposition process (e.g., a PVD deposition process or the like). In this configuration, the source assembly 570 includes a target 572, a magnetron assembly 571, a source assembly wall 573, a lid 574, and a sputtering power source 575. The magnetron assembly 571 includes a magnetron region 579 in which the magnetron 571a is rotated by use of a magnetron rotation motor 576 during processing. The target 572 and magnetron assembly 571 are typically cooled by the delivery of a cooling fluid (e.g., DI water) to the magnetron region 579 from a fluid recirculation device (not shown). The magnetron 571a includes a plurality of magnets 571b that are configured to generate magnetic fields that extends below the lower surface of the target 572 to promote a sputtering process that is being performed in the processing region 560 during a PVD deposition process.

Alternate configurations of the processing station 160, which are adapted to perform CVD, PECVD, ALD, PEALD, etch, or thermal processes, the source assembly 570 will generally include different hardware components. In one example, the source assembly 570 of a processing station that is adapted to perform a PECVD deposition process or etch process will typically include a gas distribution plate, or showerhead, that is configured to deliver a precursor gas or etching gas into the processing region 560 and across a surface of a substrate disposed within the processing station 160 during processing. In this case, the magnetron assembly 571 and target are not used, and the sputtering power source 575 can be replaced with a RF power source that is configured to bias the gas distribution plate.

The substrate support actuation assembly 590 includes a pedestal lift assembly 591 and a pedestal assembly 524. The pedestal lift assembly 591 includes a lift actuator assembly 568 and a lift mounting assembly 566, which is coupled to the base 519 of the processing station 160. During operation the lift actuator assembly 568 and lift mounting assembly 566 are configured to position the pedestal assembly 524 in at least a transfer position (FIG. 5), which is positioned vertically (Z-direction) below the transfer arm 210 (i.e., transfer plane), and a processing position (FIG. 6), which is vertically above the transfer arm 210. Further, the lift actuator assembly 568 and the lift mounting assembly 566 apply vertical motion, in the +Z direction, to the pedestal assembly 524 to pick the electrostatic chuck 187 off of the transfer arm 210. Additionally, the lift actuator assembly 568 and the lift mounting assembly 566 apply vertical motion, in the −Z direction, to the pedestal assembly 524 to position the electrostatic chuck 187 on the transfer arm 210.

The lift actuator assembly 568 is coupled to the pedestal shaft 592, which is supported by bearings (not shown) that are coupled to the base 519 to guide the pedestal shaft 592 as it is translated by the lift actuator assembly 568. A bellows assembly (not shown) is used to form a seal between the outer diameter of the pedestal shaft 592 and a portion of the base 519, such that a vacuum environment created within the transfer region 501 by use of the pump 554 is maintained during normal operation.

The pedestal assembly 524 includes a substrate support 526 that is coupled to the pedestal shaft 592. The pedestal assembly 524 includes a heater power source 595, an electrostatic chuck power source 596 and a backside gas source 597. A substrate support 526 supports the electrostatic chuck 187 and the substrate 186 when it is positioned within the processing region 560 of the processing station 160.

The substrate support 526 comprises pins 540 and 542. The pins 540 are coupled to the heater power source 595. The pedestal assembly 524 includes two or more pins 540. Further, the pins 540 are configured to mate (e.g., physically and electrically couple) with the terminals 214 of the electrostatic chuck 187. The heater power source 595 provides an AC power signal or signals. The heater power source 595 provides an AC power signal having a current in a range of about 20 A to about 30 A to the pins 540 which is provided to the heating elements 372 of the electrostatic chuck 187 via the terminals 214. In other embodiments, the heater power source 595 provides an AC power signal having a current of less than 20 A or greater than 30 A.

The pins 542 of the substrate support 526 mate with the terminals 216 of the electrostatic chuck 187. The substrate support 526 includes two or more pins 542. In such embodiments, each of the pins 542 is configured to couple to a different one of the terminals 216. For example, a first one of the pins 542 is configured to couple to a first one of the terminals 216 and a second one of the pins 542 is configured to couple to a second one of the terminals 216. The pins 542 are coupled to the electrostatic chuck power source 596.

The electrostatic chuck power source 596 provides DC power signals to the pins 542. The pins 542 couple the DC power signals to the terminals 216 and to the chucking electrodes 370 (FIG. 3) of the electrostatic chuck 187 to electrically chuck the substrate 186 to the electrostatic chuck 187. In one embodiment, the electrostatic chuck power source 596 provides a positive DC power signal to a first one of the pins 542 and a negative DC power signal to a second one of the pins 542 to electrically chuck the substrate 186 to the electrostatic chuck 187. The DC power signals drive the pins 542, the terminals 216, and the chucking electrodes 370 of the electrostatic chuck 187 in a bi-polar configuration such that a first DC power signal is positive and a second DC power signal is negative. The magnitudes of the voltage of the DC power signals may be the same. For example, a first and second DC power signal have a magnitude of about 1500 V, where the first DC power signal is about 1500 V and the second DC power signal is about −1500 V. Alternatively, the DC power signals have a magnitude greater than or less than about 1500 V. In other embodiments, the magnitude of a first one of the DC power signals differs from the magnitude of a second one of the DC power signals.

The pins 540 and 542 are removably coupled or non-removably (or permanently) coupled to the substrate support 526 of the pedestal assembly 524. For example, in one embodiment, the pins 540 and/or 542 are removably coupled and may be attached and removed from the pedestal assembly 524 such that the pins 540 and/or 542 may be replaced without damaging the substrate support 526 and/or the pedestal assembly 524. The contact between the pins 540 and 542 and the terminals 214 and 216 causes wear to the pins 540 and 542. Over time, the pins 540 and 542 may need to be replaced. Removably coupling the pins 540 and 542 to the pedestal assembly 524 allows the pins 540 and 542 to be removed and replaced when wear affects the operation of the pins 540 and/or 542.

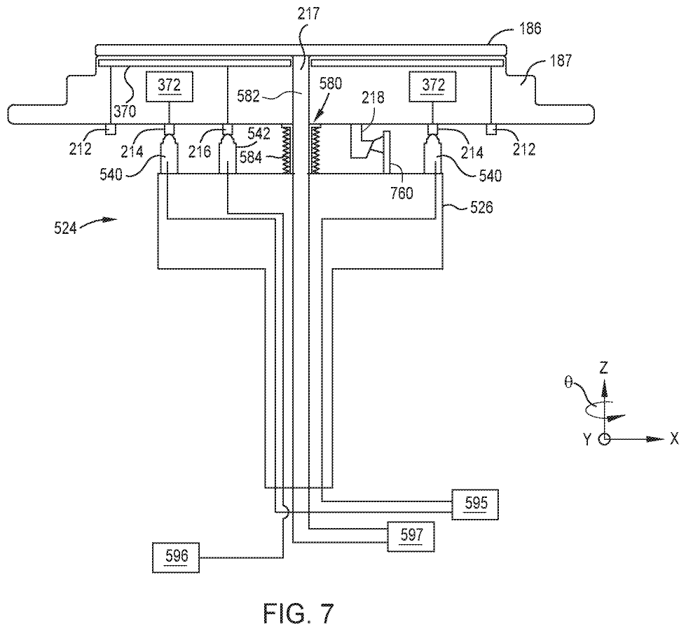

The substrate support 526 of the pedestal assembly 524 includes flexible element 580 (FIGS. 5 and 7). The flexible element 580 includes a passageway 582 and bellows 584. The flexible element 580 is configured to generate a seal against a bottom surface of the electrostatic chuck 187. A backside gas is provided via the backside gas source 597 to a passageway 582 of the flexible element 580. The backside gas flows through the passageway 582 into the space between the substrate 186 and the electrostatic chuck 187 to improve the uniformity of the thermal conductivity between the substrate 186 and the electrostatic chuck 187, improving the uniformity of the deposition of materials onto the substrate 186. The backside gas is nitrogen, helium, or argon, among others.

In the embodiment of FIG. 6, the substrate 186 and the electrostatic chuck 187 are positioned in a processing position below the source assembly 570. When in the processing position the region 564 of the electrostatic chuck 187 forms a “seal” with a portion of a sealing assembly 535 of a process kit assembly 530. The process kit assembly 530 generally includes a process region shield 532 in addition to the sealing assembly 535. The station wall 534 includes a first port that is coupled to a vacuum pump 565 and is configured to evacuate the processing region 560 through a circumferential gap formed between an upper portion of the process region shield 532, lower surface of the target 572 and portion of the isolation ring 533 and station wall 534 during processing. The station wall 534 is coupled to a gas source assembly 589, and is configured to deliver one or more process gases (e.g., Ar, N₂) to the processing region 560 through a circumferential plenum during processing.

Generating a seal between the region 564 of the electrostatic chuck 187 and the sealing assembly 535 substantially fluidly isolates the processing region 560 from the transfer region 501. Thus, in the processing region 560, the electrostatic chuck 187, the sealing assembly 535, the process region shield 532, the station wall 534, the isolation ring 533 and target 572 substantially enclose and define the processing region 560. In some embodiments, the “seal” between the region 564 of the electrostatic chuck 187 and the sealing assembly 535 is formed between the region 564 of the electrostatic chuck 187 and the upper plate 535a of the sealing assembly 535. The “seal” may be created at a sealing region that is formed by physical contact between a surface of the region 564 of the electrostatic chuck 187 and a surface of the upper plate 535a. The flexible bellows assembly 535b of the sealing assembly 535 is configured to be extended in the vertical direction (e.g., +Z direction) as the region 564 of the electrostatic chuck 187 is placed in contact with the surface of the upper plate 535a of the sealing assembly 535 by the lift actuator assembly 568. The compliant nature of the flexible bellows assembly will allow any misalignment or planarity differences between the surface of the region 564 of the electrostatic chuck 187 and the surface of the upper plate 535a of the sealing assembly 535 to be taken up so that a reliable and repeatable seal can be formed. The bellows 535b may be a stainless steel bellows assembly or Inconel bellows assembly, among others.

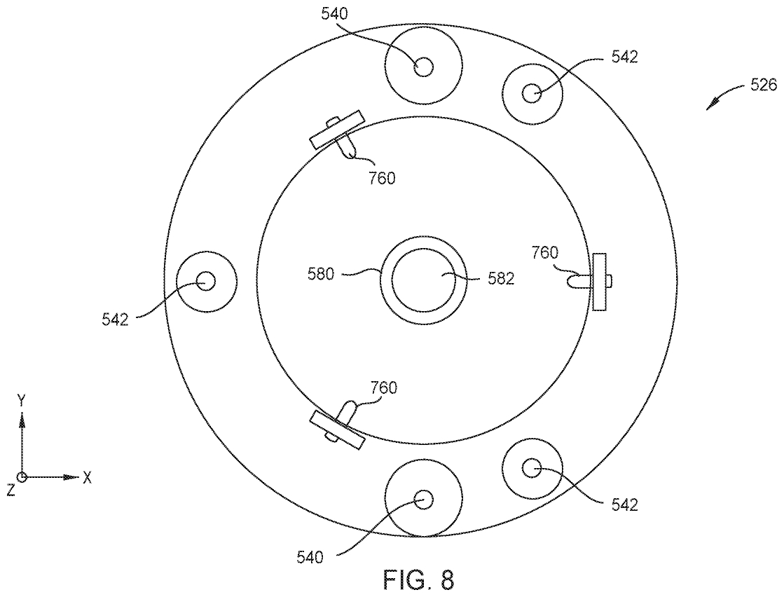

FIG. 7 illustrates a side view of the pedestal assembly 524, the substrate support 526, the electrostatic chuck 187, and the substrate 186, according to one more embodiments. FIG. 8 is a top plan view of the substrate support 526, according to one or more embodiments. The substrate support 526 includes pins 540, pins 542, and alignment elements 760. While the substrate support 526 is illustrated has having two pins 540 in FIG. 8, in other embodiments, the substrate support 526 includes more than or less than two pins 540. Further, while the substrate support 526 is illustrated has having three pins 542 in FIG. 8, in other embodiments, the substrate support 526 includes more than or less than three pins 542.

Each of the alignment elements 760 is configured to interact with a centering element 218 of the electrostatic chuck 187 to align the electrostatic chuck 187 and the substrate 186 with the substrate support 526. In one embodiment, the alignment elements 760 are positioned closer to the flexible element 580 than the pins 540 and/or the pins 542. Alternatively, the pins 540 and/or the pins 542 are positioned closer to the flexible element 580 than the alignment elements 760. The substrate support 526 includes three alignment elements 760 that are spaced a distance apart in is a plane (e.g., X-Y plane), as illustrated in FIG. 8. Alternatively, the substrate support 526 includes more than or less than three alignment elements 760.

The pins 540 and 542 may have a flat surface, a convex surface, a concave surface, or a grooved surface, among others, relative to the X-Y plane. A pin having a grooved surface includes one or more grooves having angled sides. The pins 540 and 542 are comprised of molybdenum (Mo) or tungsten (W), or a combination thereof. Alternatively, the pins 540 and 542 may be comprised of a material other than Mo or W, or a combination of materials including or not including Mo and W. The pins 540 and 542 have a surface roughness in a range of about 2 Ra to about 6 Ra. Alternatively, the pins 540 and 542 may have a surface roughness of less than 2 Ra or greater than about 6 Ra.

The terminals 212, 214, and 216 (FIG. 7) may have a flat surface, a convex surface, a concave surface, or a grooved surface, among others, relative to the X-Y plane. The terminals 212, 214, and 216 are comprised of molybdenum (Mo) or tungsten (W), or a combination thereof. Alternatively, the terminals 212, 214, and 216 may be comprised of a material other than Mo or W, or a combination of materials including or not including Mo and W. The terminals 212, 214, and 216 have a surface roughness in a range of about 2 Ra to about 6 Ra. Alternatively, the terminals 212, 214, and 216 may have a surface roughness of less than 2 Ra or greater than about 6 Ra.

The terminals 212, 214, and 216 and the pins 540 and 542 may have a similarly shaped surface. For example, the terminals 212, 214, and 216 and the pins 540 and 542 have one of a flat, a convex, concave, and a grooved shape. In other embodiments, the terminals 212, 214, and 216 have one of a flat, convex, concave, and a grooved shape and the pins 540 and 542 have a different one of a flat, convex, concave, and a grooved shape. In one example embodiment, the terminals 212, 214, 216 have a flat shape and the pins 540, 542 have a convex shape.

The terminals 212, 214, and 216 and the pins 540 and 542 may be comprised of similar materials or different materials. For example, the terminals 212, 214, and 216 and the pins 540 and 542 are formed of a first material (e.g., Mo or W, among others). Alternatively, the terminals 212, 214, and 216 are formed from a first material or materials and the pins 540 and 542 are formed from a second material or materials.

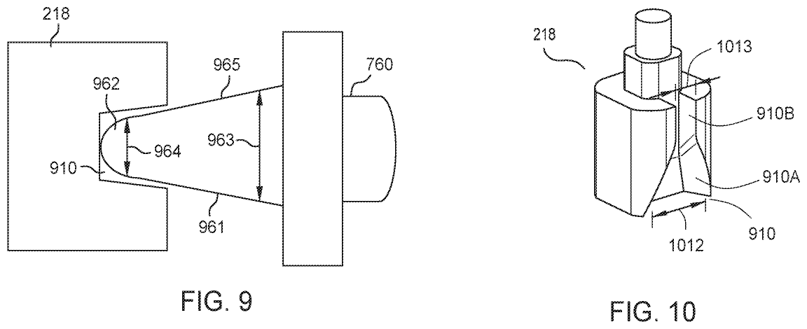

The alignment elements 760 aid in centering the electrostatic chuck 187 on the substrate support 526. During the alignment process, the substrate support 526 of the pedestal assembly 524 is moved toward the electrostatic chuck 187. As the alignment elements 760 contact the centering elements 218, the alignment elements 760 alter the position of the electrostatic chuck 187 such that the alignment elements 760 are aligned with a slot (e.g., the slot 910 of FIG. 9) of the centering elements 218 and a passageway 217 of the electrostatic chuck 187 is aligned with the passageway 582 of the flexible element 580. The alignment elements 760 may alter one or more of the X, Y, Z and Θ position of the electrostatic chuck 187. For example, in response to contact between the alignment elements 760 and the centering elements 218, the position of the electrostatic chuck 187 is moved in one or more of the X, Y, Z, and Θ position to align the passageway 217 of the electrostatic chuck 187 with the passageway 582 of the flexible element 580. The alignment elements 750 are formed from Alumina (Al₂O₃), Silicon Carbide, Sapphire, or a combination thereof. The centering elements 218 are formed from Kovar, SST-304 (stainless steel-304), and Tungsten. In one embodiment, the centering elements are formed from Tungsten and the alignment elements 750 are formed from Alumina. In other embodiments, other material combinations are used.

As illustrated in FIG. 9, the extended region (e.g., the knob) 961 of the alignment element 760 fits within the slot 910 of the centering element 218. The extended region 961 includes end 962 and body 965. The end 962 has a spherical shape. Alternatively, or additionally, the end of the extended region 961 that interfaces with the centering element 218 has one or more straight and/or angled portions. Further, the body 965 of the extended region of the alignment element 760 has a conical shape. Alternatively, the body 965 has other shapes. For example, the body 965 may have a cylindrical shape, among others. The end 962 has a diameter 964 and the body 965 has a diameter 963. The diameter 964 of the end 962 is less than the diameter 963 of the body 965. Alternatively, the diameter 964 is equal to or greater than the diameter 963.

As is described above, the alignment elements 760 and the centering elements 218 work in unison to center the electrostatic chuck 187 over the substrate support 526. During the alignment process, as the substrate support 526 of the pedestal assembly 524 is moved toward the electrostatic chuck 187, the extended region 961 of each alignment element 760 begin to interact with a slot 910 of a corresponding centering element 218. Further, as additional movement is applied to the substrate support 526 of the pedestal assembly 524, the extended region 961 of each alignment element 760 moves within a corresponding slot of a corresponding centering element 218, altering one or more of the X, Y, Z, and Θ position of the electrostatic chuck 187 relative to the pedestal assembly 524. Accordingly, the electrostatic chuck 187 is centered over the substrate support 526 and the passageway 217 of the electrostatic chuck 187 is aligned with the passageway 582 of the flexible element 580. Centering the electrostatic chuck 187 with the substrate support 526 aligns the passageway 582 of the flexible element 580 with the passageway 217 of the electrostatic chuck 187, such that a backside gas may flow through the passageway 217 and into the space between the electrostatic chuck 187 and the substrate 186. Further, centering the electrostatic chuck 187 with the substrate support 526 aligns the pins 540 with the terminals 214 and the pins 542 with the terminals 216 to facilitate an electrical connection between the pins 540, 542 and the terminals 214, 216. Accordingly, power signals (e.g., AC power signals and DC power signals) may be communicated from the pins 540, 542 to the terminals 214 and 216, and the heating elements 372 and the chucking electrodes 370 may be driven.

FIG. 10 illustrates an example centering element 218, according to one or more embodiments. As illustrated, the slot 910 includes a first region 910a and a second region 910b. The diameter of the first region 910a is wider than the diameter of the second region 910b. Further, the center of the first region 910a is aligned with the center of the second region 910b. Accordingly, as an alignment element 760 first contacts the slot 910 at region 910a, the alignment element 760 is guided into the second region 910b centering the electrostatic chuck 187 with the substrate support 526.

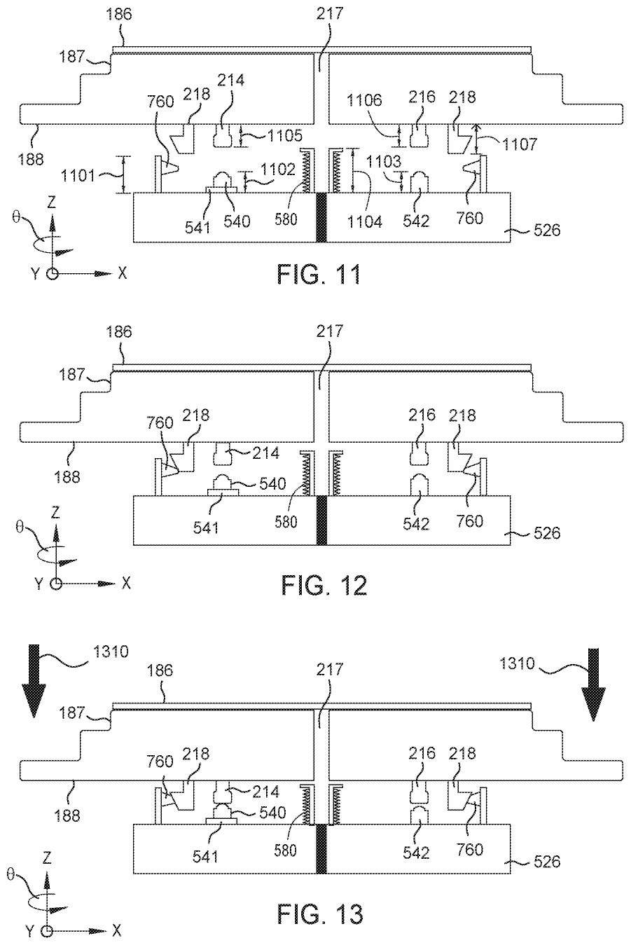

In FIGS. 11, 12, and 13, the transfer arm 210 and the details of the processing station 160 have been omitted to simplify the related discussion. For example, in FIG. 11, the transfer arm 210 supporting the electrostatic chuck 187 and the substrate 186 is omitted.

The height 1101 of the alignment element 760 (e.g., the distance that the alignment element 760 extends from the surface of the substrate support 526) is greater than the height 1102, 1103 of the pins 540 and/or 542. Further, the height 1107 of the centering element 218 (e.g., the distance that the centering element 218 extends from the surface of the electrostatic chuck 187) is greater than the height 1105 and/or 1106 of the terminals 214, 216. The height 1101 of the alignment element 760 relative to the heights 1102, 1103 of the pins 540, 542 and the height of the centering element 218 relative to the height 1105 of the terminal 214 and/or the height 1106 of the terminals 216 may be selected such that the alignment elements 760 meet the centering elements 218 before the pins 540, 542 meet the terminals 214, 216.

The pedestal lift assembly 591 moves the substrate support 526 vertically (+Z direction) toward the electrostatic chuck 187 such that the alignment elements 760 interface with the centering elements 218. The alignment elements 760 interface with the centering elements 218 before the pins 540 and 542 interface with the terminals 214 and 216, and the flexible element 580 interfaces with the bottom surface 188 of the electrostatic chuck 187. As is described above, the extended region 961 of each alignment element 760 mates (interfaces) with a slot 910 of a corresponding centering element 218. In response to the vertical motion of the substrate support 526, each of the alignment elements 760 interfaces with the first region 910a of a slot 910 of a corresponding centering element 218.

As is illustrated in FIG. 12, the pedestal lift assembly 591 moves the substrate support 526 vertically (+Z direction) toward the electrostatic chuck 187 such that the alignment elements 760 are completely interfaced with the centering elements 218 and the electrostatic chuck 187 is centered over the substrate support 526. For example, the passageway 217 is aligned with the flexible element 580, the terminals 214 are aligned with the pins 540, and the terminals 216 are aligned with the pins 542.

With reference to FIGS. 9 and 10, as the alignment elements 760 first interface with the centering elements 218, the extended region 961 of the alignment elements 760 interface with the first region 910a of each centering element 218. The width of the first region 1012 is less than the width 1013 of the second region 910b, accordingly, while the substrate support 526 is moved vertically, the extended region 961 of each alignment element 760 is guided into the second region 910b of a corresponding centering element 218, centering the electrostatic chuck 187 over the substrate support 526. Centering the electrostatic chuck 187 over the substrate support 526 aligns the pins 540, 542 with respective ones of the terminals 214, 216 and the passageway 217 with the flexible element 580.

As illustrated in FIG. 13, the pedestal lift assembly 591 continues to apply vertical motion to the substrate support 526 such that the substrate support 526 is moved vertically (+Z direction) toward the electrostatic chuck 187, and the pins 540 are mated to the terminals 214. The pins 540 include a compliance element 541, where in response to the pins 540 contacting the terminals 214 and supporting at least a portion of the combined weight of the electrostatic chuck 187 and the substrate 186, the pins 540 move in the +Z direction relative to the bottom surface of the electrostatic chuck 187 and the top surface of the substrate support 526. The compliance element 541 may be a spring or similar element that allows the pins 540 to move in the vertical direction (±Z direction) in response to weight of the electrostatic chuck 187 being taken up by the terminals 214 and supporting the weight of electrostatic chuck 187 and the substrate 186. The compliance element 541 of each of the pins 540 ensures that an electrical connection is established between each of the pins 540 and one of the terminals 214. The electrical connection allows a power source signal to be communicated from the power source 595 to the heating elements 372 via the pins 540 and the terminals 214. In response to mating with the terminals 214, the pins 540 support about 10 percent of the combined weight of the electrostatic chuck 187 and the substrate 186 (e.g., force 1310 of FIG. 13). In other embodiments, the pins 540 support less than or more than 10 percent of the combined weight of the electrostatic chuck 187 and the substrate 186.

To mate the pins 540 with the terminals 214, the pedestal lift assembly 591 moves about 10 mm in the vertical direction (+Z direction) relative to the substrate support 526. Alternatively, the pedestal lift assembly 591 moves the substrate support 526 less than about 10 mm or greater than about 10 mm in the vertical direction (+Z direction) to mate the pins 540 with the terminals 214.

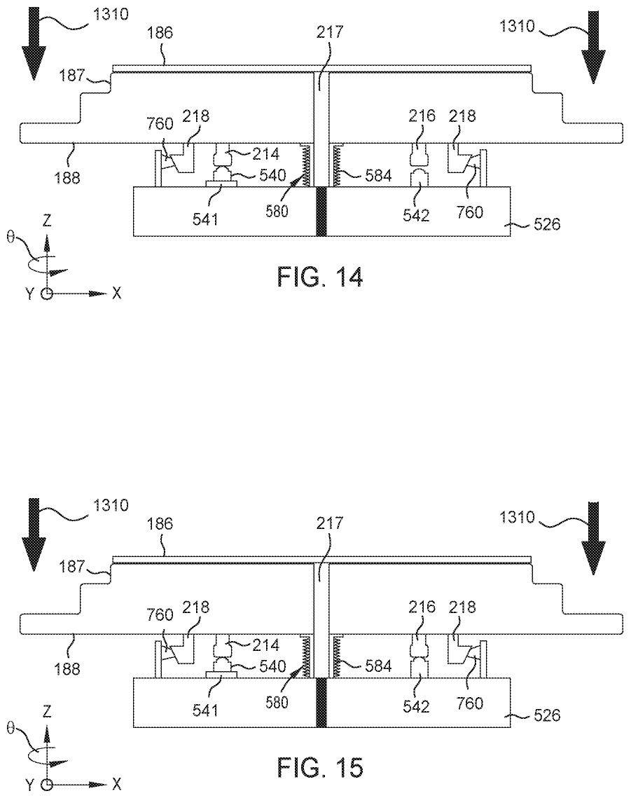

As illustrated in FIG. 14, in response to the pedestal lift assembly 591 applies further vertical motion to the substrate support 526, the compliance elements 541 of the pins 540 move in the −Z direction such that the flexible element 580 contacts the bottom surface 188 of electrostatic chuck 187. The flexible element 580 forms a seal with the bottom surface 188 of the electrostatic chuck 187 and the passageway 217. Accordingly, a backside gas may be provided to a gap between the substrate 186 and the electrostatic chuck 187 via the flexible element 580 and the passageway 217.

The pedestal lift assembly 591 moves the substrate support 526 about 1 mm vertically in the +Z direction to establish an interface between the flexible element 580 and the electrostatic chuck 187. Alternatively, the pedestal lift assembly 591 moves the substrate support 526 less than about 1 mm or greater than about 1 to generate a separable gas tight seal between the flexible element 580 and the bottom surface 188 of the electrostatic chuck 187. The gas tight seal between the flexible element 580 and the electrostatic chuck 187 is formed such that the gas tight seal may be broken when the electrostatic chuck 187 is removed from the substrate support 526 and transferred out of the corresponding processing region. The separable gas tight seal provides a gas tight seal when the electrostatic chuck 187 is interfaced with the substrate support 526, but may also be broken such that the electrostatic chuck 187 may be removed from the substrate support 526 and transferred out of the corresponding processing region. Another electrostatic chuck 187 may then be mounted to the substrate support 526 and a separable gas tight seal is formed between that electrostatic chuck and the flexible element 580. Accordingly, the separable gas tight seal allows for a seal to be formed between the flexible element 580 and electrostatic chucks as the electrostatic chucks are transferred into and out of the corresponding processing region.

The flexible element 580 supports about 20 percent to about 30 percent of the weight of the electrostatic chuck 187 and the substrate 186 (e.g., the force 1310). Alternatively, the flexible element 580 supports less than about 20 percent or more than about 30 percent of the combined weight of the electrostatic chuck 187 and the substrate 186.

The bellows 584 compresses in response to the combined weight of the electrostatic chuck 187 and the substrate 186 such that in response to additional vertical motion (+Z direction) applied by the pedestal lift assembly 591 to the substrate support 526, the pins 542 contact the terminals 216 (FIG. 15). The pins 542 mate with the terminals 216 forming an electrical connection that allows a power source signal to be provided to the chucking electrodes 370 from the power source 596. The pins 542 support about 10 percent to about 30 percent of the combined weight of the electrostatic chuck 187 and the substrate 186. Alternatively, the pins 542 support less than about 10 percent or greater than about 30 percent of the combined weight of the electrostatic chuck 187 and the substrate 186. Further, the entire combined weight of the electrostatic chuck 187 and the substrate 186 is supported by the pins 540, the flexible element 580, and the pins 542. Accordingly, the electrostatic chuck 187 and the substrate 186 are supported by the substrate support 526 and not by the transfer arm 210.

The pedestal lift assembly 591 to the substrate support 526 continues to move the electrostatic chuck 187 and the substrate 186 such that the region 564 of the electrostatic chuck 187 contacts the sealing element 535 and the processing region 560 is formed.

With further reference to FIG. 11, the heights 1101, 1102, 1103, 1104, 1105, 1106 and 1107 are configured such that the alignment elements 760 interface with the centering elements 218 before the pins 540 interface with the terminals 214, pins 540 interface with the terminals 214 before the flexible element 580 interfaces with a surface of the electrostatic chuck 187, and the flexible element 580 interfaces with the electrostatic chuck 187 before the pins 542 interface with the terminals 216.

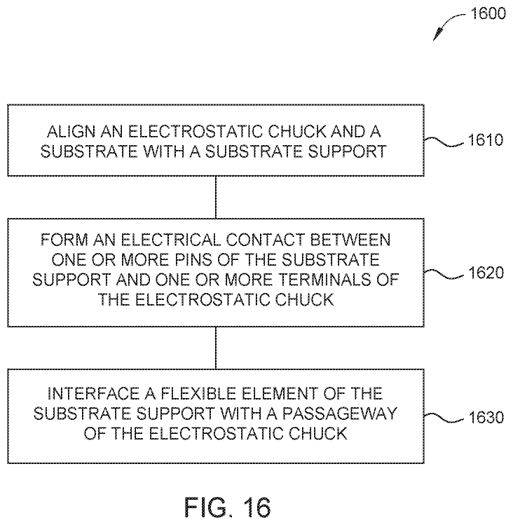

FIG. 16 illustrates a method 1600 for transferring an electrostatic chuck (e.g., the electrostatic chuck 187) and a substrate (e.g., the substrate 186) onto a substrate support (e.g., the substrate support 526) of a processing region (e.g., the processing region 160). At 1610, the electrostatic chuck 187 and the substrate 186 are aligned with the substrate support 526. For example, to align the electrostatic chuck 187 and the substrate 186 with the substrate support 526, the interface elements 760 of the substrate support 526 are aligned with centering elements 218 of the electrostatic chuck 187. For example, as is illustrated in FIGS. 11 and 12, vertical motion is applied to the substrate support 526 to interface the interface element 760 with the centering elements 218. The electrostatic chuck 187 and the substrate 186 is supported by a transfer arm 210.

At 1620, an electrical contact is formed between one or more pins of the substrate support and one or more terminals of the electrostatic chuck. With reference to FIGS. 11, 12, and 13, vertical motion is applied to the substrate support 526 such that the pins 540 and/or the pins 542 make an electrical connection with the terminals 214 and/or 216, respectively. As is discussed above, a portion of the weight of the electrostatic chuck 187 and the substrate 186 is supported by the pins 540 and 542 such that that amount of weight supported by the transfer arm 210 is reduces as compared to before an electrical contact is formed between the pins 540 and 542.

At 1630, a flexible element interfaces with the electrostatic chuck. For example, the flexible element 580 interfaces with the passageway 217 of the electrostatic chuck 187. Interface with the passageway 217 forms a separable gas tight seal between the flexible element 580 and the electrostatic chuck 187. Further a backside gas flows through the passageway 217 and between the substrate 186 and the electrostatic chuck 187 via the flexible element 580. The flexible element 580 compresses in response to the weight of the electrostatic chuck 187 and the substrate 186. Accordingly, the flexible element 580 supports part of the weight of the electrostatic chuck 187 and the substrate 186. The flexible element 580 interfaces with the electrostatic chuck 187 in response to vertical motion applied to the substrate support 526. Further, as additional vertical motion is applied to the substrate support 526 after the flexible element 580 interfaces with the electrostatic chuck 187, the flexible element 580 compresses and the pin 542 forms an electrical connection with the terminal 216. In one embodiment, once the pin 542 forms the electrical connection with the terminal 216, the electrostatic chuck 187 and the substrate 186 is completely supported by the substrate support 526, and the transfer arm 210 may be removed from the processing region (e.g., the processing region 160). Further, after the transfer arm 210 is removed, the vertical motion is applied to the substrate support 526, the electrostatic chuck 187, and the substrate 186 to place the substrate in a processing position within a processing volume for processing.

To remove the electrostatic chuck 187 and the substrate 186 from the substrate support 526, the above process is reversed. For example, the transfer arm 210 is positioned within the processing region 160, and vertical motion in the opposite direction as above (e.g., in the −Z direction) is applied to the substrate support 526 such that the electrostatic chuck 187 and the substrate 186 interfaces with and is supported by the transfer arm 210 and can be transferred from the processing region.

While the foregoing is directed to embodiments of the present disclosure, other and further embodiments of the disclosure may be devised without departing from the basic scope thereof, and the scope thereof is determined by the claims that follow.

What is claimed is:

1. A substrate support for a processing chamber, the substrate support comprising:
a plurality of pins configured to mate with terminals of an electrostatic chuck, plurality of pins are configured to be coupled to one or more power sources; and
a plurality of alignment elements configured to interface with a plurality of centering elements of the electrostatic chuck to center the electrostatic chuck with the substrate support, each of the plurality of alignment elements is configured to interface with a slot of a corresponding one of the plurality of centering elements.

2. The substrate support of claim 1, wherein a number of the plurality of alignment elements is three.

3. The substrate support of claim 1, wherein the substrate support further comprises a flexible element positioned at a center of the substrate support, and wherein the plurality of alignment elements are positioned closer to the flexible element than the plurality of pins.

4. The substrate support of claim 1, wherein each of the plurality of alignment elements has an extended region that interfaces with the slot of the corresponding one of the plurality of centering elements.

5. The substrate support of claim 4, wherein an end the extended region of each of the plurality of alignment elements has a spherical shape.

6. The substrate support of claim 5, wherein a body of the extended region of each of the plurality of alignment elements has a conical shape.

7. The substrate support of claim 6, wherein the body of each of the extended region has a concave region.

8. A processing region comprising:
one or more power sources configured to provide power signals;
a pedestal assembly comprising a substrate support, the substrate support comprising:
a plurality of pins configured to mate with a plurality of terminals of an electrostatic chuck, plurality of pins are coupled to the one or more power sources; and
a plurality of alignment elements configured to interface with a plurality of centering elements of the electrostatic chuck to center the electrostatic chuck with the substrate support, each of the plurality of alignment elements is configured to interface with a slot of a corresponding one of the plurality of centering elements.

9. The processing region of claim 8, wherein a number of the plurality of alignment elements is three.

10. The processing region of claim 8, wherein the substrate support further comprises a flexible element positioned at a center of the substrate support, and wherein the plurality of alignment elements are positioned closer to the flexible element than the plurality of pins.

11. The processing region of claim 8, wherein each of the plurality of alignment elements has an extended region that interfaces with the slot of the corresponding one of the plurality of centering elements.

12. The processing region of claim 11, wherein an end the extended region of each of the plurality of alignment elements has a spherical shape.

13. The processing region of claim 12, wherein a body of the extended region of each of the plurality of alignment elements has a conical shape.

14. The processing region of claim 13, wherein the body of each of the extended region has a concave region.

15. The processing region of claim 8 further comprising a pedestal lift assembly configured to vertically move the substrate support toward the electrostatic chuck.

16. The processing region of claim 15, wherein the plurality of alignment elements are configured to interface with the plurality centering elements before one or more of the plurality of pins mate with one or more of the plurality of terminals in response to vertical movement applied by the pedestal lift assembly.

17. The processing region of claim 8, wherein each of the slots of each of the centering elements has a first region having a first diameter and a second region having a second diameter, the first diameter is greater than the second region.

18. The processing region of claim 17, wherein an extended region of each of the plurality of alignment elements interfaces with the first region before the second region.

19. The processing region of claim 18, wherein when the extended region of each of the plurality of alignment elements interfaces with the second region, the plurality of pins mate with the plurality of terminals.

20. A method for transferring an electrostatic chuck and a substrate onto a substrate support of a processing region, the method comprising:
aligning the electrostatic chuck and the substrate with the substrate support by interfacing a plurality of alignment elements of the substrate support with a plurality of centering elements of the electrostatic chuck;
forming an electrical contact between one more pins of the substrate support and one or more terminals of the electrostatic chuck; and
interfacing a flexible element of the substrate support with a passageway of the electrostatic chuck.
